(19) United States
(12) Patent Application Publication
(10) Pub. No.: US 2017/0207407 A1
(43) Pub. Date: Jul. 20, 2017

(54) ORGANIC LIGHT EMITTING APPARATUS, DISPLAY DEVICE HAVING THE SAME, AND FABRICATING METHOD THEREOF

(71) Applicant: BOE TECHNOLOGY GROUP CO., LTD., Beijing (CN)

(72) Inventor: Chin Lung Liao, Beijing (CN)

(73) Assignee: BOE TECHNOLOGY GROUP CO., LTD., Beijing (CN)

(21) Appl. No.: 15/107,087

(22) PCT Filed: Feb. 22, 2016
(86) PCT No.: PCT/CN2016/074217

§ 371 Date: Jun. 21, 2016

(30) Foreign Application Priority Data
Jul. 17, 2015 (CN) 201510425486.8

(51) Int. Cl. H01L 51/50; H01L 51/56

(52) U.S. Cl. CPC H01L 51/5008; H01L 51/5056; H01L 51/5012; H01L 51/5004; H01L 51/56; H01L 2251/552; H01L 51/006

(57) ABSTRACT

The present application discloses an organic light emitting apparatus comprising a hole transport layer comprising a hole transport material; a light emitting layer comprising a light emitting material; and an interface modification layer comprising an interface modification material between the hole transport layer and the light emitting layer for improving energy level matching of the hole transport layer and the light emitting layer. The interface modification material has an energy level between those of the hole transport material and the light emitting material.

### CROSS-REFERENCE TO RELATED APPLICATION

This application claims priority to Chinese Patent Application No. 201510425486.8, filed on Jul. 17, 2015, the contents of which are incorporated by reference in the entirety.

### FIELD

The present invention relates to display technology, more particularly, to an organic light emitting apparatus, a display device having the same, and a fabricating method thereof.

### BACKGROUND

Organic light emitting diodes (OLED) use the principles of electrophosphorescence to convert electrical energy in an OLED into light in a highly efficient manner. OLEDs are self-emitting apparatuses that contain sold material and do not require a backlight. Having the advantages of a wide viewing angle and fast response, they have found a wide range of applications in display field.

### SUMMARY

In one aspect, the present invention provides an organic light emitting apparatus comprising a hole transport layer comprising a hole transport material; a light emitting layer comprising a light emitting material; and an interface modification layer comprising an interface modification material between the hole transport layer and the light emitting layer for improving energy level matching of the hole transport layer and the light emitting layer.

Optionally, the interface modification material has an energy level between those of the hole transport material and the light emitting material.

Optionally, the energy level is a highest occupied molecular orbital (HOMO) level.

Optionally, the interface modification layer is sandwiched by the hole transport layer and the light emitting layer.

Optionally, the interface modification layer comprises a plurality of interface modification sub-layers, the energy levels of the plurality of interface modification sub-layers gradually transition from the energy level of the hole transport material towards that of the light emitting material.

Optionally, the energy levels of the plurality of interface modification sub-layers are in the range of about −5.7 ev to about −5.3 ev, and gradually transition towards −5.3 ev.

Optionally, the hole transport material is a polymer, the interface modification material is a small molecule.

Optionally, the interface modification material having hole transport property.

Optionally, the interface modification material is a phenylamine compound.

Optionally, the interface modification material is selected from a group consisting of N,N′-Bis(naphthalene-2-yl)-N,N′-bis(phenyl)-benzidine, N,N′-bis(3-methylphenyl)-N,N′-diphenyl-benzidine, 4,4′-Cyclohexylidenebis[N,N-bis(4-methylphenyl)aniline], and N,N′-diphenyl-N,N′-di-p-tolyl-Benzidine.

Optionally, the hole transport material is selected from a group consisting of polythiophene, polyaniline, polypyrrole, and a mixture comprising poly-3,4-ethylenedioxythiophene and poly(sodium-p-styrenesulfonate).

Optionally, the light emitting material is a blue light emitting material comprising a host material selected from a group consisting of 3-tert-Butyl-9,10-di(naphth-2-yl)anthracene, 9,10-Di(1-naphthyl)anthracene, 4,4′-Bis(2,2-diphenylvinyl)-1,1′-biphenyl, 1,3,6,8-Tetraphenylpyrene, 9,9′-spirobifluorene, 4,4′-Bis(N-carbazolyl)-1,1′-biphenyl, 3,3′-Bis(N-carbazolyl)-1,1′-biphenyl; and a guest material selected from a group consisting of 2,5,8,11-Tetra-tert-butylperylene, BCzVBi, 4,4′-[1,4-phenylenedi-(1E)-2,1-ethenediyl]bis[N,N-diphenylbenzenamine], a weight percentage of the host material in the blue light emitting material is in the range of about 93% to about 99%, and a weight percentage of the guest material in the blue light emitting material is in the range of about 1% to about 7%.

Optionally, the light emitting material is a red light emitting material selected from a group consisting of 4,4′-Bis(N-carbazolyl)-1,1′-biphenyl doped with 5,6,11,12-tetraphenyltetracene, poly (9,9-dioctylfluorene) doped with Tris[1-phenylisoquinolinato-C2,N]iridium(III), poly (fluorene-alt-Carbazole) doped with Tris[1-phenylisoquinolinato-C2,N]iridium(III), poly (9,9-dioctylfluorene) doped with 5,6,11,12-tetraphenyltetracene, poly (fluorene-alt-Carbazole) doped with 5,6,11,12-tetraphenyltetracene, and polyvinylpyrrolidone doped with Tris[1-phenylisoquinolinato-C2,N]iridium(III).

Optionally, the light emitting material is a green light emitting material selected from a group consisting of 1,3,5-Tris(bromomethyl)benzene doped with N,N′-Dimethylquinacridone, poly (fluorene-alt-Carbazole) doped with Tris(2-phenylpyridine)iridium, poly (fluorene-alt-Carbazole) doped with N,N′-Dimethylquinacridone, and polyvinylpyrrolidone doped with Tris(2-phenylpyridine)iridium.

Optionally, the organic light emitting apparatus further comprises one or more of a hole injection layer, an electron transport layer and an electron injection layer.

Optionally, the interface modification layer has a thickness in the range of about 0.5 nm to about 5 nm.

Optionally, the interface modification layer has a thickness of about 1 nm.

Optionally, the organic light emitting apparatus is a bottom-emitting organic light emitting apparatus comprising a top electrode layer on a side of the light emitting layer distal to the interface modification layer; a bottom electrode layer on a side of the hole transport layer distal to the interface modification layer; and a base substrate on a side of the bottom electrode layer distal to the hole transport layer; the top electrode layer is light reflective, and the bottom electrode layer is light transmissive.

Optionally, the organic light emitting apparatus is a top-emitting organic light emitting apparatus comprising a top electrode layer on a side of the light emitting layer distal to the interface modification layer; a bottom electrode layer on a side of the hole transport layer distal to the interface modification layer; and a base substrate on a side of the bottom electrode layer distal to the hole transport layer; the top electrode layer is light transmissive, and the bottom electrode layer is light reflective.

In another aspect, the present invention provides a method of fabricating an organic light emitting apparatus, comprising forming a hole transport layer comprising a hole transport material on a base substrate; forming an interface modification layer comprising an interface modification material on a side of the hole transport layer distal to the base substrate for improving energy level matching of the hole transport layer and the light emitting layer; and forming a light emitting layer comprising a light emitting material on a side of the interface modification layer distal to the hole transport layer; the interface modification material has an energy level between those of the hole transport material and the light emitting material.

Optionally, the step of forming the interface modification layer comprises forming a plurality of interface modification sub-layers, the energy levels of the plurality of interface modification sub-layers gradually transition from the energy level of the hole transport material towards that of the light emitting material.

Optionally, the step of forming the hole transport layer comprises coating the hole transport material on the base substrate to produce a coated substrate; and drying the coated substrate thereby forming the hole transport layer.

Optionally, the step of forming the interface modification layer comprises vapor depositing the interface modification material on a side of the hole transport layer distal to the base substrate.

Optionally, a vapor deposition rate of the interface modification material is in the range of about 0.01 nm/s to about 0.1 nm/s.

Optionally, the step of forming the light emitting layer comprises vapor depositing the light emitting material on a side of the interface modification layer distal to the hole transport layer.

In another aspect, the present invention provides a display device comprising an organic light emitting apparatus described herein or fabricated by a method described herein.

### BRIEF DESCRIPTION OF THE FIGURES

The following drawings are merely examples for illustrative purposes according to various disclosed embodiments and are not intended to limit the scope of the present invention.

FIG. 1 is a diagram illustrating the structure of an organic light emitting apparatus in certain embodiments.

FIG. 2 is a diagram illustrating the structure of an organic light emitting apparatus in certain embodiments.

FIG. 3 is a flow chart illustrating a method of fabricating an organic light emitting apparatus in certain embodiments.

### DETAILED DESCRIPTION

The disclosure will now describe more specifically with reference to the following embodiments. It is to be noted that the following descriptions of some embodiments are presented herein for purpose of illustration and description only. It is not intended to be exhaustive or to be limited to the precise form disclosed.

Conventional OLEDs typically include a base substrate, a bottom electrode, a hole injection layer, a hole transport layer, a light emitting layer, an electron transport layer, an electron injection layer and a top electrode sequentially disposed on the base substrate. The hole transport layer includes a hole transport material suitable for solution-based deposition, i.e., the hole transport layer is formed by a solution-based deposition process. The light emitting layer includes a light emitting material suitable for vapor deposition, i.e., the light emitting layer is formed by a vapor deposition process.

The present disclosure identifies several issues associated with the convention OLEDs. The hole transport material is a material suitable for solution-based deposition whereas the light emitting material is a material suitable for vapor deposition, resulting in poor energy level matching between the hole transport layer and the light emitting layer. Consequently, the transport of holes from the hole transport layer to the light emitting layer is hindered due to the poor energy level matching, resulting in a low light emission efficiency.

In one aspect, the present disclosure provides a superior organic light emitting apparatus having an exceptional light emission efficiency. In some embodiments, the organic light emitting apparatus includes a hole transport layer having a hole transport material, a light emitting layer having a light emitting material, and an interface modification layer having an interface modification material between the hole transport layer and the light emitting layer. Optionally, the interface modification material has an energy level between those of the hole transport material and the light emitting material. For example, the interface modification material has a highest occupied molecular orbital (HOMO) energy level between those of the hole transport material and the light emitting material. In some embodiments, the HOMO energy level of a light emitting layer is about −5.3 ev, e.g., in the range of about −5.4 ev to about −5.2 ev, about −5.5 ev to about −5.3 ev, about −5.6 ev to about −5.3 ev, or about −5.5 to about −5.2 ev. In some embodiments, the HOMO energy level of a hole transport layer is in the range of about −5.7 ev to about −5.3 ev. Optionally, the energy levels of the interface modification layer is in the range of about −5.7 ev to about −5.3 ev, e.g., about −5.6 ev to about −5.3 ev, about −5.5 ev to about −5.3 ev, about −5.4 ev to about −5.3 ev, about −5.7 ev to about −5.4 ev, about −5.6 ev to about −5.4 ev, about −5.5 ev to about −5.4 ev, about −5.7 ev to about −5.5 ev, or about −5.6 ev to about −5.5 ev.

In some embodiments, the organic light emitting apparatus includes a plurality of interface modification layers between the hole transport layer and the light emitting layer. Optionally, the energy levels of the plurality of interface modification layers are between those of the hole transport material and the light emitting material. Optionally, the energy levels of the plurality of interface modification layers gradually transition (e.g., in stepped fashion) from the energy level of the hole transport material towards that of the light emitting material. Optionally, the energy levels of the plurality of interface modification layers gradually transition (e.g., in stepped fashion) from about −5.7 ev towards about −5.3 ev. Optionally, the energy levels of the plurality of interface modification layers gradually transition (e.g., in stepped fashion) from about −5.5 ev towards about −5.3 ev. Optionally, the energy levels of the plurality of interface modification layers gradually transition (e.g., in stepped fashion) within the range of about −5.7 ev to about −5.3 ev, e.g., about −5.6 ev to about −5.3 ev, about −5.5 ev to about −5.3 ev, about −5.4 ev to about −5.3 ev, about −5.7 ev to about −5.4 ev, about −5.6 ev to about −5.4 ev, about −5.5 ev to about −5.4 ev, about −5.7 ev to about −5.5 ev, or about −5.6 ev to about −5.5 ev.

In some embodiments, the HOMO energy level of the interface modification material is within 1.0 ev (e.g., within 0.8 ev, within 0.6 ev, within 0.4 ev, within 0.2 ev) of the HOMO energy level of the light emitting material. In some embodiments, the HOMO energy level of the interface modification material is within 1.0 ev (e.g., within 0.8 ev, within 0.6 ev, within 0.4 ev, within 0.2 ev) of the HOMO energy level of the hole transport material. In some embodiments, the HOMO energy level of the interface modification material is within 1.0 ev (e.g., within 0.8 ev, within 0.6 ev, within 0.4 ev, within 0.2 ev) of the HOMO energy level of the hole transport material and the HOMO energy level of the light emitting material.

In some embodiments, the hole transport material is a polymer, the interface modification material is a small molecule. Optionally, the interface modification material is a small molecule having a molecular weight in the range of 10 Da to 2000 Da, e.g., 10 Da to 1500 Da, 10 Da to 1000 Da, 10 Da to 900 Da, 10 Da to 800 Da, 10 Da to 700 Da, 100 Da to 2000 Da, e.g., 100 Da to 1500 Da, 100 Da to 1000 Da, 100 Da to 900 Da, 100 Da to 800 Da, or 100 Da to 700 Da. Optionally, the interface modification material includes a mixture of compounds, each of which has an energy level between those of the hole transport material and the light emitting material. Optionally, the hole transport material is a co-polymer or a mixture of polymers.

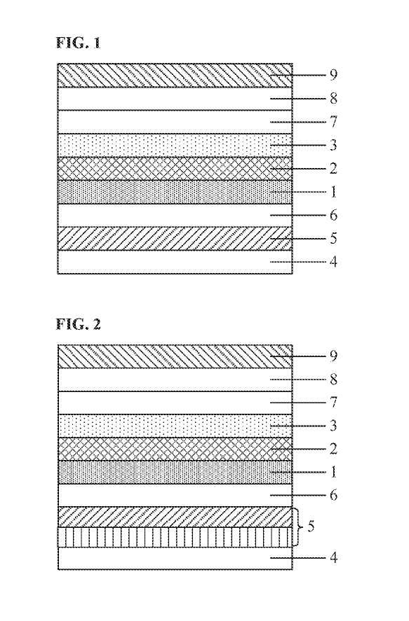

FIG. 1 is a diagram illustrating the structure of an organic light emitting apparatus in certain embodiments. Referring to FIG. 1, the organic light emitting apparatus in the embodiment includes a hole transport layer 1, a light emitting layer 3, and an interface modification layer 2 between the hole transport layer 1 and the light emitting layer 3. Optionally, the interface modification layer 2 is sandwiched by the hole transport layer 1 and the light emitting layer 3. The interface modification layer 2 includes an interface modification material having hole transport property. The energy level of the interface modification layer 2 is between the energy level of the hole transport layer 1 and the energy level of the light emitting layer 3. Thus, an excellent energy level matching may be achieved between the interface modification layer 2 and the hole transport layer 1, as well as between the interface modification layer 2 and the light emitting layer 3. The holes may be efficiently transported from hole transport layer 1 to the light emitting layer 3, resulting in an organic light emitting apparatus having an exceptional light emission efficiency.

In some embodiments, the hole transport layer 1 includes a hole transport material suitable for solution-based deposition, i.e., the hole transport layer 1 is formed by a solution-based deposition process. In some embodiments, the light emitting layer 3 includes a light emitting material suitable for vapor deposition, i.e., the light emitting layer 3 is formed by a vapor deposition process. In some embodiments, the interface modification material is a material suitable for vapor deposition, and the interface modification layer 2 is formed by a vapor deposition process. When the hole transport layer 1 is formed by a solution-based deposition process, the surface of the hole transport layer 1 is relatively uneven as compared to a surface formed by a vapor deposition process. By forming an interface modification layer 2 on the hole transport layer 1, the hindered hole transport and low light emission efficiency caused by the uneven surface of the hole transport layer 1 can be overcame (e.g., eliminated or much reduced) by the inclusion of the interface modification layer 2, thereby improving the light emission efficiency of the organic light emitting apparatus.

Various appropriate materials for making an interface modification layer may be used. In some embodiments, the interface modification material is a material suitable for vapor deposition. In some embodiments, the interface modification material is a phenylamine based compounds such as phenylamine derivatives, examples of which include, but are not limited to, N,N′-Bis(naphthalene-2-yl)-N,N′-bis(phenyl)-benzidine, N,N′-bis(3-methylphenyl)-N,N′-diphenyl-benzidine, 4,4′-Cyclohexylidenebis[N,N-bis(4-methylphenyl)aniline], and N,N′-diphenyl-N,N′-di-p-tolyl-Benzidine.

Various appropriate materials for making a hole transport layer may be used. In some embodiments, the hole transport material is a material suitable for a solution-based deposition process. In some embodiments, the hole transport material is selected from a group consisting of polythiophene, polyaniline, polypyrrole, and a mixture comprising poly-3,4-ethylenedioxythiophene and poly(sodium-p-styrenesulfonate).

Various appropriate materials for making a light emitting layer may be used. In some embodiments, the light emitting material is a material suitable for vapor deposition. In some embodiments, the light emitting material includes a blue light emitting material, a red light emitting material, and/or a green light emitting material.

Various appropriate blue light emitting materials may be used. In some embodiments, the blue light emitting material includes a host material and a guest material. Optionally, the host material is selected from a group consisting of 3-tert-Butyl-9,10-di(naphth-2-yl)anthracene, 9,10-Di(1-naphthyl)anthracene, 4,4′-Bis(2,2-diphenylvinyl)-1,1′-biphenyl, 1,3,6,8-Tetraphenylpyrene, 9,9′-spirobifluorene, 4,4′-Bis(N-carbazolyl)-1,1′-biphenyl, 3,3′-Bis(N-carbazolyl)-1,1′-biphenyl. Optionally, the guest material is selected from a group consisting of 2,5,8,11-Tetra-tert-butylperylene, BCzVBi, 4,4′-[1,4-phenylenedi-(1E)-2,1-ethenediyl]bis[N,N-diphenylbenzenamine]. Optionally, the weight percentage of the host material in the blue light emitting material is in the range of about 93% to about 99%, e.g., about 93% to about 95%, about 95% to about 97%, or about 97% to about 99%. Optionally, the weight percentage of the guest material in the blue light emitting material is in the range of about 1% to about 7%, e.g., about 1% to about 3%, about 3% to about 5%, or about 5% to about 7%.

Various appropriate red light emitting materials may be used. In some embodiments, the red light emitting material is selected from a group consisting of 4,4′-Bis(N-carbazolyl)-1,1′-biphenyl doped with 5,6,11,12-tetraphenyltetracene, poly (9,9-dioctylfluorene) doped with Tris[1-phenylisoquinolinato-C2,N]iridium(III), poly (fluorene-alt-Carbazole) doped with Tris[1-phenylisoquinolinato-C2,N]iridium(III), poly (9,9-dioctylfluorene) doped with 5,6,11,12-tetraphenyltetracene, poly (fluorene-alt-Carbazole) doped with 5,6,11,12-tetraphenyltetracene, and polyvinylpyrrolidone doped with Tris[I-phenylisoquinolinato-C2,N]iridium(III).

Various appropriate green light emitting materials may be used. In some embodiments, the green light emitting material is selected from a group consisting of 1,3,5-Tris(bromomethyl)benzene doped with N,N′-Dimethylquinacridone, poly (fluorene-alt-Carbazole) doped with Tris(2-phenylpyridine)iridium, poly (fluorene-alt-Carbazole) doped with N,N′-Dimethylquinacridone, and polyvinylpyrrolidone doped with Tris(2-phenylpyridine)iridium.

In some embodiments, the organic light emitting apparatus further includes one or more of a hole injection layer, an electron transport layer and an electron injection layer. Optionally, when the organic light emitting apparatus is in operation, electrons travels from a top electrode or a bottom electrode into the electron transport layer, and enter into the light emitting layer 3. Optionally, when the organic light emitting apparatus is in operation, holes travel from the hole injection layer into the hole transport layer 1, then are transported from the hole transport layer 1 via the interface modification layer 2 into the light emitting layer 3. The light emitting layer 3 emits light by excitons produced in recombination of the electrons and holes within the light emitting layer 3.

In some embodiments, the interface modification layer 2 has a thickness such that holes may be efficiently transported into the light emitting layer 3 from the hole transport layer 1. Optionally, the interface modification layer 2 has a relatively smaller thickness as compared to the hole transport layer 1. Optionally, the interface modification layer has a thickness in the range of about 0.1 nm to about 15 nm, e.g., about 0.1 nm to about 1 nm, about 0.1 nm to about 2 nm, about 0.1 nm to about 0.5 nm, about 0.2 nm to about 0.5 nm, about 0.2 nm to about 5 nm, about 0.5 nm to about 1 nm, about 0.5 nm to about 3 nm, about 0.5 nm to about 5 nm, about 0.5 nm to about 10 nm, or about 0.5 nm to about 15 nm. Optionally, the interface modification layer has a thickness in the range of about 0.5 nm to about 5 nm. Optionally, the interface modification layer has a thickness of about 1 nm. By forming an interface modification layer 2 on the hole transport layer 1, the hindered hole transport and low light emission efficiency caused by the uneven surface of the hole transport layer 1 can be overcame (e.g., eliminated or much reduced) by the inclusion of the interface modification layer 2, thereby improving the light emission efficiency of the organic light emitting apparatus.

Various embodiments of organic light emitting apparatuses may be practiced. For example, the organic light emitting apparatus may be a top-emitting organic light emitting apparatuses or a bottom-emitting organic light emitting apparatuses. Any appropriate organic light emitting apparatus may be modified according to the present disclosure to have an interface modification layer 2 between a hole transport layer 1 and a light emitting layer 3. Examples include, but are not limited to, an organic light emitting layer discussed in Chinese Patent Application Nos. 201510222251.9, 201510324123.5, and 201510325751.5, the contents of which are incorporated herein by reference in its entirety.

FIG. 1 is a diagram illustrating the structure of a bottom-emitting organic light emitting apparatus in certain embodiments. Referring to FIG. 1, the organic light emitting apparatus in the embodiment further includes a top electrode layer 9 on a side of the light emitting layer 3 distal to the interface modification layer 2, a bottom electrode layer 5 on a side of the hole transport layer 1 distal to the interface modification layer 2, and a base substrate 4 on a side of the bottom electrode layer 5 distal to the hole transport layer 1. The top electrode layer 9 is light reflective, and the bottom electrode layer 5 is light transmissive. Light emits from the organic light emitting apparatus through the bottom electrode layer 5 and the base substrate 4. Optionally, the bottom electrode 3 is made of a material comprising indium tin oxide (e.g., a transparent indium tin oxide layer). Optionally, the bottom electrode 3 is an indium tin oxide film on the base substrate 4. Optionally, the surface resistivity of the indium tin oxide film is less than 30 Ω/square and larger than zero. Optionally, the indium tin oxide film has a thickness of about 70 nm. Optionally, the top electrode 9 is made of a material comprising aluminum. Optionally, the top electrode 9 has a thickness of about 120 nm. In some embodiments, the organic light emitting apparatus further includes a hole injection layer 6, an electron transport layer 7, and an electron injection layer 8. Optionally, the organic light emitting apparatus includes a bottom electrode layer 5, a hole injection layer 6, a hole transport layer 1, an interface modification layer 2, a light emitting layer 3, an electron transport layer 7, an electron injection layer 8, and a top electrode layer 9 sequentially on a base substrate 4.

FIG. 2 is a diagram illustrating the structure of a top-emitting organic light emitting apparatus in certain embodiments. Referring to FIG. 1, the organic light emitting apparatus in the embodiment further includes a top electrode layer 9 on a side of the light emitting layer 3 distal to the interface modification layer 2, a bottom electrode layer 5 on a side of the hole transport layer 1 distal to the interface modification layer 2, and a base substrate 4 on a side of the bottom electrode layer 5 distal to the hole transport layer 1. The top electrode layer 9 is light transmissive, and the bottom electrode layer 5 is a light reflective. Light emits from the organic light emitting apparatus through the top electrode layer 9. Optionally, the bottom electrode layer 5 is a single layer, the single layer being both a conductive layer and a reflective layer. Optionally, the bottom electrode layer 5 includes two sub-layers, a conductive sub-layer and a reflective sub-layer. Optionally, the first sub-layer is proximal to the base substrate 4 and is a reflective sub-layer, the second sub-layer is distal to the base substrate 4 and is a conductive sub-layer. Optionally, the reflective sub-layer is made of a material comprising silver, aluminum, or other reflective metals or alloys. Optionally, the conductive sub-layer is made of a material comprising indium tin oxide. Optionally, the top electrode 9 is made of a material comprising indium tin oxide (e.g., a transparent indium tin oxide layer). In some embodiments, the organic light emitting apparatus further includes a hole injection layer 6, an electron transport layer 7, and an electron injection layer 8. Optionally, the organic light emitting apparatus includes a bottom electrode layer 5, a hole injection layer 6, a hole transport layer 1, an interface modification layer 2, a light emitting layer 3, an electron transport layer 7, an electron injection layer 8, and a top electrode layer 9 sequentially on a base substrate 4.

Optionally, the hole transport layer 1 has a thickness of about 20 nm, and the hole transport material is selected from a group consisting of polythiophene, polyaniline, polypyrrole, and a mixture comprising poly-3,4-ethylenedioxythiophene and poly(sodium-p-styrenesulfonate).

Optionally, the interface modification layer 2 has thickness of about 1 nm, and the interface modification material is selected from a group consisting of N,N′-Bis(naphthalene-2-yl)-N,N′-bis(phenyl)-benzidine, N,N′-bis(3-methylphenyl)-N,N′-diphenyl-benzidine, 4,4′-Cyclohexylidenebis[N,N-bis(4-methylphenyl)aniline], and N,N′-diphenyl-N,N′-di-p-tolyl-Benzidine.

Optionally, the blue light emitting layer 3 has a thickness of about 20 nm, the host material for the blue light emitting material is selected from a group consisting of 3-tert-Butyl-9,10-di(naphth-2-yl)anthracene, 9,10-Di(1-naphthyl)anthracene, 4,4′-Bis(2,2-diphenylvinyl)-1,1′-biphenyl, 1,3,6,8-Tetraphenylpyrene, 9,9′-spirobifluorene, 4,4′-Bis(N-carbazolyl)-1,1′-biphenyl, 3,3′-Bis(N-carbazolyl)-1,1′-biphenyl, the guest material for the blue light emitting material is selected from a group consisting of 2,5,8,11-Tetra-tert-butylperylene, BCzVBi, 4,4′-[1,4-phenylenedi-(1E)-2,1-ethenediyl]bis[N,N-diphenylbenzenamine], the weight percentage of the host material in the blue light emitting material is in the range of about 93% to about 99%, and a weight percentage of the guest material in the blue light emitting material is in the range of about 1% to about 7%.

Optionally, the base substrate 4 is a transparent glass substrate.

Optionally, the hole injection layer 6 includes a hole injection material. Optionally, the hole injection material is selected from a group consisting of poly(3,4-ethylenedioxythiophene) polystyrene sulfonate (PEDOT:PSS), polythiophene, polyaniline, and polypyrrole. Optionally, the hole injection layer 6 has a thickness of about 25 nm.

Optionally, the electron transport layer 7 includes an electron transport material. Optionally, the electron transport material is selected from the group consisting of 4,7,-diphenyl-1,10-phenanthroline, 2,9-Bis(naphthalen-2-yl)-4,7-diphenyl-1,10-phenanthroline, 2,9-dimethyl-4,7-diphenyl-1,10-phenanthroline, 8-hydroxyquinoline aluminum, and 8-hydroxyquinoline lithium. Optionally, the electron transport layer 7 has a thickness of about 20 nm.

Optionally, the electron injection layer 8 includes an electron injection material. Optionally, the electron injection material is selected from a group consisting of lithium fluoride and 8-hydroxyquinoline lithium. Optionally, the electron injection layer 8 has a thickness of about 1 nm.

Optionally, the organic light emitting apparatus has a light emitting area of about 2 mm×about 2 mm.

Table 1 shows a comparison of light emission efficiency between the present light emitting apparatus in certain embodiments (Apparatus A) and a conventional light emitting apparatus (Apparatus B). The only difference between Apparatus A and Apparatus B is that Apparatus B does not include an interface modification layer 2 whereas Apparatus A includes an interface modification layer 2 having a thickness of about 1 nm.

TABLE 1
Current efficiencies and external quantum efficiencies of Apparatus A and
Apparatus B measured at a luminance of 1000 nits.

| | | Current efficiency | External quantum |
|---|---|---|---|
| | Voltage (V) | (Cd/A) | efficiency (%) |
| Apparatus A | 3.3 | 4.6 | 6.1 |
| Apparatus B | 3.3 | 3.4 | 4.3 |

The term “external quantum efficiency” refers to the ratio of the radiation energy emitted from the Apparatus A or Apparatus B to the electrical energy input into the apparatus, respectively. The current efficiency of the apparatus at a certain voltage is determined by dividing the electroluminescence radiance of the apparatus by the current density needed to run the apparatus. As shown in Table 1, the external quantum efficiency in Apparatus A is improved by 42% over Apparatus B, the current efficiency in Apparatus A is improved by 35% over Apparatus B. The light emission efficiency of the present light emitting apparatus is dramatically improved over the conventional light emitting apparatus.

In one aspect, the present disclosure provides an organic light emitting apparatus having a hole transport layer, a light emitting layer, and an interface modification layer between (e.g., sandwiched by) the hole transport layer and the light emitting layer. The interface modification layer includes an interface modification material having hole transport property. The energy level of the interface modification layer is between the energy level of the hole transport layer and the energy level of the light emitting layer. Thus, an excellent energy level matching may be achieved between the interface modification layer and the hole transport layer, as well as between the interface modification layer and the light emitting layer. The holes may be efficiently transported from hole transport layer to the light emitting layer, resulting in an organic light emitting apparatus having an exceptional light emission efficiency.

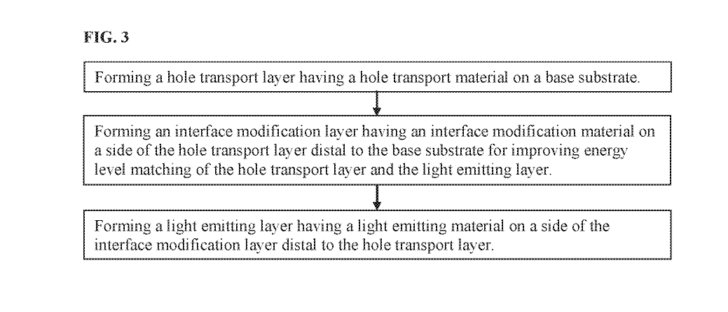

In another aspect, the present disclosure provides a method of fabricating an organic light emitting apparatus. FIG. 3 is a flow chart illustrating a method of fabricating an organic light emitting apparatus in certain embodiments. Referring to FIG. 3, the method in the embodiment includes forming a hole transport layer having a hole transport material on a base substrate, forming an interface modification layer having an interface modification material on a side of the hole transport layer distal to the base substrate, and forming a light emitting layer having a light emitting material on a side of the interface modification layer distal to the hole transport layer. The interface modification layer includes an interface modification material having hole transport property. The energy level of the interface modification layer is between the energy level of the hole transport layer and the energy level of the light emitting layer.

An organic light emitting apparatus manufactured by the present methods in some embodiments includes an interface modification layer between (e.g., sandwiched by) the hole transport layer and the light emitting layer. The interface modification layer includes an interface modification material having hole transport property. The energy level of the interface modification layer is between the energy level of the hole transport layer and the energy level of the light emitting layer. Thus, an excellent energy level matching may be achieved between the interface modification layer and the hole transport layer, as well as between the interface modification layer and the light emitting layer. The holes may be efficiently transported from hole transport layer to the light emitting layer, resulting in an organic light emitting apparatus having an exceptional light emission efficiency.

In some embodiments, the hole transport layer includes a hole transport material suitable for solution-based deposition. Optionally, the hole transport layer is formed by a solution-based deposition process. Optionally, the step of forming the hole transport layer includes coating the hole transport material on the base substrate to produce a coated substrate and drying the coated substrate thereby forming the hole transport layer.

Optionally, prior to forming the hole transport layer, the base substrate is pre-treated. Optionally, the pretreatment includes photolithography on a transparent glass base substrate having a transparent indium tin oxide thin film thereby forming a bottom electrode pattern. Optionally, the pretreatment further includes ultrasonic cleaning of the base substrate sequentially in deionized water, acetone, and dehydrated alcohol, drying the base substrate using nitrogen gas, and treating the base substrate using an oxygen plasma. The pretreatment further increases light emission efficiency of the organic light emitting apparatus by creating a clean base substrate surface, changing the work function of indium tin oxide thin film, and improving hole transport efficiency from the bottom electrode to the hole transport layer.

In some embodiments, the interface modification material is a material suitable for vapor deposition. Optionally, the interface modification layer is formed by a vapor deposition process. Optionally, the step of forming the interface modification layer includes vapor depositing the interface modification material on a side of the hole transport layer distal to the base substrate. Optionally, the vapor deposition is performed under a pressure less than 5×10⁻⁴ Pa in a deposition chamber. Optionally, a vapor deposition rate may be chosen to achieve an interface modification layer that eliminates or reduces the unevenness of the hole transport layer surface, and at the same time avoids a lengthy vapor deposition time. Optionally, the vapor deposition rate of the interface modification material is in the range of about 0.01 nm/s to about 0.1 nm/s. Optionally, the vapor deposition rate of the interface modification material is 0.05 nm/s.

In some embodiments, the light emitting layer comprises a light emitting material suitable for vapor deposition, the light emitting layer is formed by a vapor deposition process, the step of forming the light emitting layer comprising vapor depositing the light emitting material on a side of the interface modification layer distal to the hole transport layer. Optionally, the vapor deposition is performed under a pressure less than 5×10⁻⁴ Pa in a deposition chamber.

In some embodiment, the method further includes, after forming the light emitting layer, forming an electron transport layer by vapor depositing an electron transport material on the base substrate under a pressure less than 5×10⁻⁴ Pa in a vapor deposition chamber.

In some embodiment, the method further includes, after forming the electron transport layer, forming an electron injection layer by vapor depositing an electron injection material on the base substrate under a pressure less than 5×10⁻⁴ Pa in a vapor deposition chamber.

In some embodiment, the method further includes, after forming the electron injection layer, forming a top electrode layer by vapor depositing a top electrode material on the base substrate under a pressure less than 5×10⁻⁴ Pa in a vapor deposition chamber.

Optionally, an open mask may be used in vapor deposition for forming various layers of the organic light emitting apparatus. Optionally, a metal mask may be used in vapor deposition for forming an electrode made of a material comprising aluminum. Optionally, a vapor deposition rate of an aluminum material of about 0.5 nm/s is used. Optionally, a vapor deposition rate of the interface modification material is in the range of about 0.01 nm/s to about 0.1 nm/s. Optionally, a vapor deposition rate of about 0.1 nm/s is used for a material other than the aluminum material and the interface modification material.

Based on the above, the present disclosure provides a method of fabricating an organic light emitting apparatus having superior properties including an exceptional light emission efficiency. In some embodiments, the method includes forming a hole transport layer on a base substrate, forming an interface modification layer on a side of the hole transport layer distal to the base substrate, and forming a light emitting layer on a side of the interface modification layer distal to the hole transport layer. The interface modification layer includes an interface modification material having hole transport property. The energy level of the interface modification layer is between the energy level of the hole transport layer and the energy level of the light emitting layer. Thus, an excellent energy level matching may be achieved between the interface modification layer and the hole transport layer, as well as between the interface modification layer and the light emitting layer. The holes may be efficiently transported from hole transport layer to the light emitting layer, resulting in an organic light emitting apparatus having an exceptional light emission efficiency.

In another aspect, the present disclosure provides a display device comprising an organic light emitting apparatus described herein or manufactured by a method described herein. Examples of appropriate display devices includes, but are not limited to, an electronic paper, a mobile phone, a tablet computer, a television, a monitor, a notebook computer, a digital album, a gps, etc. The display device of the present disclosure has an exceptional light emission efficiency.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”. “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An organic light emitting apparatus, comprising:
a hole transport layer comprising a hole transport material;
a light emitting layer comprising a light emitting material; and
an interface modification layer comprising an interface modification material between the hole transport layer and the light emitting layer for improving energy level matching of the hole transport layer and the light emitting layer;
wherein the interface modification material has an energy level between those of the hole transport material and the light emitting material.

2. The organic light emitting apparatus of claim 1, wherein the energy level is a highest occupied molecular orbital (HOMO) level.

3. The organic light emitting apparatus of claim 1, wherein the interface modification layer is sandwiched by the hole transport layer and the light emitting layer.

4. The organic light emitting apparatus of claim 1, wherein the interface modification layer comprises a plurality of interface modification sub-layers, the energy levels of the plurality of interface modification sub-layers gradually transition from the energy level of the hole transport material towards that of the light emitting material.

5. The organic light emitting apparatus of claim 4, wherein the energy levels of the plurality of interface modification sub-layers are in the range of about −5.7 ev to about −5.3 ev, and gradually transition towards −5.3 ev.

6. The organic light emitting apparatus of claim 1, wherein the hole transport material is a polymer, the interface modification material is a small molecule.

7. The organic light emitting apparatus of claim 1, wherein the interface modification material having hole transport property.

8. The organic light emitting apparatus of claim 1, wherein the interface modification material is a phenylamine compound.

9. The organic light emitting apparatus of claim 8, wherein the interface modification material is selected from a group consisting of N,N′-Bis(naphthalene-2-yl)-N,N′-bis(phenyl)-benzidine, N,N′-bis(3-methylphenyl)-N,N′-diphenyl-benzidine, 4,4′-Cyclohexylidenebis[N,N-bis(4-methylphenyl)aniline], and N,N′-diphenyl-N,N′-di-p-tolyl-Benzidine.

10. The organic light emitting apparatus of claim 1, wherein the hole transport material is selected from a group consisting of polythiophene, polyaniline, polypyrrole, and a mixture comprising poly-3,4-ethylenedioxythiophene and poly(sodium-p-styrenesulfonate).

11. The organic light emitting apparatus of claim 1, wherein the light emitting material is a blue light emitting material comprising:
a host material selected from a group consisting of 3-tert-Butyl-9,10-di(naphth-2-yl)anthracene, 9,10-Di(1-naphthyl)anthracene, 4,4′-Bis(2,2-diphenylvinyl)-1,1′-biphenyl, 1,3,6,8-Tetraphenylpyrene, 9,9′-spirobifluorene, 4,4′-Bis(N-carbazolyl)-1,1′-biphenyl, 3,3′-Bis(N-carbazolyl)-1,1′-biphenyl; and
a guest material selected from a group consisting of 2,5,8,11-Tetra-tert-butylperylene, BCzVBi, 4,4′-[1,4-phenylenedi-(1E)-2,1-ethenediyl]bis[N,N-diphenylbenzenamine];
wherein a weight percentage of the host material in the blue light emitting material is in the range of about 93% to about 99%, and a weight percentage of the guest material in the blue light emitting material is in the range of about 1% to about 7%.

12. The organic light emitting apparatus of claim 1, wherein the light emitting material is a red light emitting material selected from a group consisting of 4,4′-Bis(N-carbazolyl)-1,1′-biphenyl doped with 5,6,11,12-tetraphenyltetracene, poly (9,9-dioctylfluorene) doped with Tris[1-phenylisoquinolinato-C2,N]iridium(III), poly (fluorene-alt-Carbazole) doped with Tris[1-phenylisoquinolinato-C2,N]iridium(III), poly (9,9-dioctylfluorene) doped with 5,6,11,12-tetraphenyltetracene, poly (fluorene-alt-Carbazole) doped with 5,6,11,12-tetraphenyltetracene, and polyvinylpyrrolidone doped with Tris[1-phenylisoquinolinato-C2,N]iridium(III).

13. The organic light emitting apparatus of claim 1, wherein the light emitting material is a green light emitting material selected from a group consisting of 1,3,5-Tris(bromomethyl)benzene doped with N,N′-Dimethylquinacridone, poly (fluorene-alt-Carbazole) doped with Tris(2-phenylpyridine)iridium, poly (fluorene-alt-Carbazole) doped with N,N′-Dimethylquinacridone, and polyvinylpyrrolidone doped with Tris(2-phenylpyridine)iridium.

14. (canceled)

15. (canceled)

16. (canceled)

17. (canceled)

18. (canceled)

19. A display device comprising an organic light emitting apparatus of claim 1.

20. A method of fabricating an organic light emitting apparatus, comprising:
forming a hole transport layer comprising a hole transport material on a base substrate;
forming an interface modification layer comprising an interface modification material on a side of the hole transport layer distal to the base substrate for improving energy level matching of the hole transport layer and the light emitting layer; and
forming a light emitting layer comprising a light emitting material on a side of the interface modification layer distal to the hole transport layer;
wherein the interface modification material has an energy level between those of the hole transport material and the light emitting material.

21. The method of claim 20, wherein the step of forming the interface modification layer comprises forming a plurality of interface modification sub-layers, the energy levels of the plurality of interface modification sub-layers gradually transition from the energy level of the hole transport material towards that of the light emitting material.

22. The method of claim 20, wherein the step of forming the hole transport layer comprises coating the hole transport material on the base substrate to produce a coated substrate; and drying the coated substrate thereby forming the hole transport layer.

23. The method of claim 20, wherein the step of forming the interface modification layer comprises vapor depositing the interface modification material on a side of the hole transport layer distal to the base substrate.

24. The method of claim 23, wherein a vapor deposition rate of the interface modification material is in the range of about 0.01 nm/s to about 0.1 nm/s.

25. The method of claim 20, wherein the step of forming the light emitting layer comprises vapor depositing the light emitting material on a side of the interface modification layer distal to the hole transport layer.
